(19) United States
(12) Patent Application Publication
(10) Pub. No.: US 2024/0170592 A1
(43) Pub. Date: May 23, 2024

(54) Semimetal-Monolayer Transition Metal Dichalcogenides Photodetectors for Wafer-Scale Broadband Photonics

(71) Applicant: San Francisco State University, Long Beach, CA (US)

(72) Inventor: Akm NEWAZ, San Francisco, CA (US)

(21) Appl. No.: 18/355,595

(22) Filed: Jul. 20, 2023

Related U.S. Application Data
(60) Provisional application No. 63/368,923, filed on Jul. 20, 2022.
(60) Provisional application No. 63/487,605, filed on Feb. 28, 2023.

(51) Int. Cl. H01L 31/032; H01L 31/0224; H01L 31/0232

(52) U.S. Cl. CPC H01L 31/032; H01L 31/022408; H01L 31/02327

(57) ABSTRACT

An optical detector is provided that includes: a first semimetal electrical contact; a second semimetal electrical contact; and a semimetal-transition metal dichalcogenide-semimetal layer, electrically coupled between the first and second semimetal electrical contacts.

### CROSS-REFERENCE TO RELATED APPLICATION

This patent application claims the benefit of U.S. Provisional Patent Application No. 63/368,923 filed Jul. 20, 2022, entitled, “Semimetal-Monolayer Transition Metal Dichalcogenides Photodetectors for Wafer-Scale Broadband Photonics” and claims the benefit of U.S. Provisional Patent Application No. 63/487,605, entitled “Semimetal-Monolayer Transition Metal Dichalcogenides Photodetectors for Wafer-Scale Broadband Photonics”, which are incorporated by reference herein in its entirety.

### GOVERNMENT LICENSE RIGHTS

This invention was made with government support under ECCS-2151971, awarded by the National Science Foundation, and W911NF-19-1-0007, awarded by the Department of Defense. The government has certain rights in the invention.

### BACKGROUND

Broadband photodetectors (BPD) with spectral coverage ranging from ultraviolet (UV) to near infrared (NIR) range are at the heart of many applications ranging from high-capacity optical communication, night vision, biological analysis, environmental sensors, wide spectral switches, fire monitoring, and space exploration to radiation detection. [1-4] For example, near infrared light detection capabilities enables image sensors fused with night vision systems. [5,6] Another important application is in the optical data communication system, in which the wide spectral bandwidth is used to increase optical data transmission capacity. [7]

Past research has focused on developing photodetectors that were mainly focused on their performances for a narrow wavelength spectrum, mostly due to the lack of proper materials which can absorb incident photons over broad wavelength range with excellent optoelectronic conversion efficiency. Several approaches have been explored to develop efficient broadband photodetectors based on many nanomaterials and device designs. [1,4,8-11] For example, graphene based broadband photodetector show promises as an active material for broadband photodetector. [8,10] However, low photon absorption by monolayer graphene causes poor photoresponsivity. Another extensively used research material is to employ solution processed organic Halide perovskite. [4,12] However, solution process fabrication fundamentally imposes a limitation in reliably producing uniform films over a large area, or wafer scale production.

A broadband nanoscale photodetector is disclosed that includes atomically thin 2D semiconductor device. Two-dimensional transition metal dichalcogenides (TMDs), such as MoS₂, materials provide platform for nanoscale photonics due to their atomic scale thickness, strong-light matter interaction, and favorable mechanical, and electrical properties. [13-18] Moreover, wafer scale growth of TMDs make them promising candidates for future very large scale integrated (VLSI) candidates. [19-21]

Photons impinging on a monolayer TMDs (1L-TMDs) will produce a direct band-gap optical transition, also known as the A and B transitions. [13-18] In addition, there also exists a pair of van Hove singularity (vHS) assisted excitonic transitions (referred to as C [22] and D peaks [23]) in the UV regime above approximately (3-4 eV) eV. [22] These excitons cause extraordinarily high photon absorption of 1L-TMDs (˜40% for 1L-MoS₂ [24-26]). It has been reported that the radiative lifetime of A- and B-excitons are few picoseconds. [25-27] The vHS excitons form within the continuum of the quasiparticle state, i.e., above the band edge, and decay spontaneously. [22] Due to spontaneous decay, the lifetime of the C-/D-excitons is short (T_{C}˜ 0.4 ns). [28] High absorption and shorter lifetime of the excitons create an opportunity to develop an efficient and fast nanoscale broadband photodetector.

However, when a metal contact (e.g., Au) is evaporated on a 2D molybdenum disulfide (MoS₂) and other TMDs to prepare the metal contact, interface defects are created that pin the Fermi level near the conduction band, known as the metal-induced gap states (MIGS). The formation of MIGS at the metal-semiconductor interface causes an energy barrier—which leads to high contact resistance, non-linear current-voltage (I-V) characteristics, and poor current delivery capability. [29-31] All these factors have limited the use of TMDs as next-generation photonic devices.

To unpin the Femi level, many efforts have been attempted including, indium metal contacts, [32,33] atomically flat Au metals, [34] and via contacts methods. [35] Recently, it has been reported that a semimetal-TMDs-semimetal (STMDS) device overcomes this limitation, where the MIGS are sufficiently suppressed, which results in creating ohmic contacts with ultralow contact resistance. [36,37] By using semimetal (e.g., Bi, Sn, etc.) as the contact materials, Shen et al., and Kumar et al., demonstrated the ohmic contact with resistance as low as 123 Ω·μm for Bi/1L-MoS₂/Bi and 270 Ω·μm for Sn/1L-MoS₂/Sn devices at room temperatures, respectively. [36,37]

The principal mechanism of MIGS suppression is that a semimetal has a near-zero density of states (DOS) at the Fermi level. [36] Hence, if the Fermi level of a semimetal is close to the conduction band minimum of a semiconductor, the MIGS from the conduction-band are greatly reduced. This new semimetal/TMD contact technology may pave the way towards obtaining high-performance monolayer transistors that are on-par with the current silicon semiconductors technology and will allow extending Moore's law.

### SUMMARY

An optical detector is provided that includes a first semimetal electrical contact portion, a second semimetal electrical contact portion and a transition metal dichalcogenide (TMD) layer electrically coupled between the first and second semimetal electrical contact portions.

An optical detection method is provided that includes receiving optical photon energy at a TMD monolayer electrically coupled between first and second semimetal electrical contacts. Electrical current flow comprising electrons excited by optical photon energy received at the TMD layer is measured between the first and second semimetal electrical contacts.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A is an illustrative drawing showing an array of STMDS photodetector devices formed on a semiconductor substrate.

FIG. 1B is an example graph showing Raman spectroscopy measurement from a monolayer MoS₂ of the example STMDS device of FIG. 10.

FIG. 2A is an illustrative drawing showing current-voltage (I-V) curve of STMDS test devices.

FIG. 2B is illustrative resistance of a STMDS test devices as a function of temperature.

FIG. 2C is an illustrative determination of the Schottky barrier of STMDS test devices for different bias voltages.

FIG. 3A is an illustrative graph showing photoluminescence spectrum from a test STMDS device measured at room temperature.

FIG. 3B is an illustrative graph showing photoresponsivity (current per unit light power) of a test STMDS device at different wavelength and showing photocurrent spectroscopy from an encapsulated monolayer an alternative Au-TMD-Au test device formed on a glass substrate.

FIG. 3C is an illustrative graph showing photoresponsivity of a test STMDS device at different bias voltages.

FIG. 3D is an illustrative graph showing photoresponsivity of a test STMDS device at different temperatures.

FIG. 4A is an illustrative graph showing EQE of a test STMDS device at different wavelengths.

FIG. 4B is an illustrative graph showing measurement of EQE as a function of bias voltage.

FIG. 4C is an illustrative graph showing photocurrent as a function of laser power measured.

FIG. 4D is an illustrative graph showing EQE as a function of the laser power.

FIG. 5A is an illustrative graph showing time response of a test STMDS device for a single laser pulse.

FIG. 5B is an illustrative graph showing a time response of the device for different voltages.

FIG. 5C is an illustrative graph showing time response as a function of different laser power.

FIG. 5D is an illustrative graph showing time response as a function of temperature.

FIG. 6A is an illustrative schematic diagram showing an example test STMDS device with a back-gate that is operational as a phototransistor.

FIG. 6B is an illustrative graph that shows EQE of the device of FIG. 6A for different example back-gate voltages.

FIG. 6C is an illustrative graph that shows external quantum efficiency plots for six different test STMDS devices to demonstrate the device performance variation.

FIG. 6D is an illustrative chart that shows responsivity values vs response time plot for different type of solid-state UV photodetectors reported in the literature.

FIGS. 7A-7E are illustrative drawing showing an example process to manufacture a first example STMDS photodetector.

FIG. 8 is an illustrative drawing showing the cross-section view of an example STMDS photodetector electrically coupled as a two-terminal device in accordance with some embodiments.

FIG. 9 is an illustrative drawing showing a cross-section view of a second example STMDS photodetector electrically coupled as a three-terminal device in accordance with some embodiments.

FIG. 10 is an example top planer view of an example photodetector 1000 in accordance with some embodiments.

### DETAILED DESCRIPTION

### Overview

The inventor has developed a photodetector device using the optoelectronic properties of an STMDS device. Atomically thin two-dimensional (2D) transition metal dichalcogenides (TMDs), such as MoS₂, exhibit strong-light matter interactions. However, Fermi level pinning due to metal-induced gap (MIGS) states at the metals-monolayer (1L) MoS₂ interface limits the application of optoelectronic devices based on conventional metals because of the high contact resistance of the Schottky contacts. However, a semimetal-TMD-semimetal (STMDS) device can overcome this limitation, by suppressing the MIGS sufficiently to result in ohmic contact behavior.

The following Table shows TMDs and semimetals. Different combinations of these TMDs and semimetals can be combined to produce STMDS for use as photodetector devices.

TABLE

| TMDs | Semimetals |
|---|---|
| WS₂, MoSe₂, WSe₂, MoTe₂, | As, In, Sn, Sb, Te, TI, Pb, Po, |
| WTe₂, MoS₂ | At, Bi |

An example STMDS photodetector device is disclosed herein includes a bismuth (Bi)-1L MoS₂—Bi photodetector device with ohmic contacts. For wafer-scale applications of STMDS photodetectors, full-coverage growth of 1L-TMDs is critical. Photodetector test devices comprising 1L MoS₂ TMDs were grown by solid-source chemical vapor deposition (CVD). A high photoresponsivity of 300 A/W was measured near the edge of UV regime (˜400 nm) at 77 K, which translates into an external quantum efficiency (EQE) ˜1000 or 10⁵%. The inventor found based upon photocurrent spectroscopy measurements, that the test STMDS devices are most sensitive in the UV range and also have excellent broadband photoresponsivity with spectral coverage from 380 nm to 1000 nm. The inventor found that the 90% rise time and fall time of our devices is 0.1 ms, which suggests that the test STMDS photodetector devices can operate at the speed of ˜10 kHz.

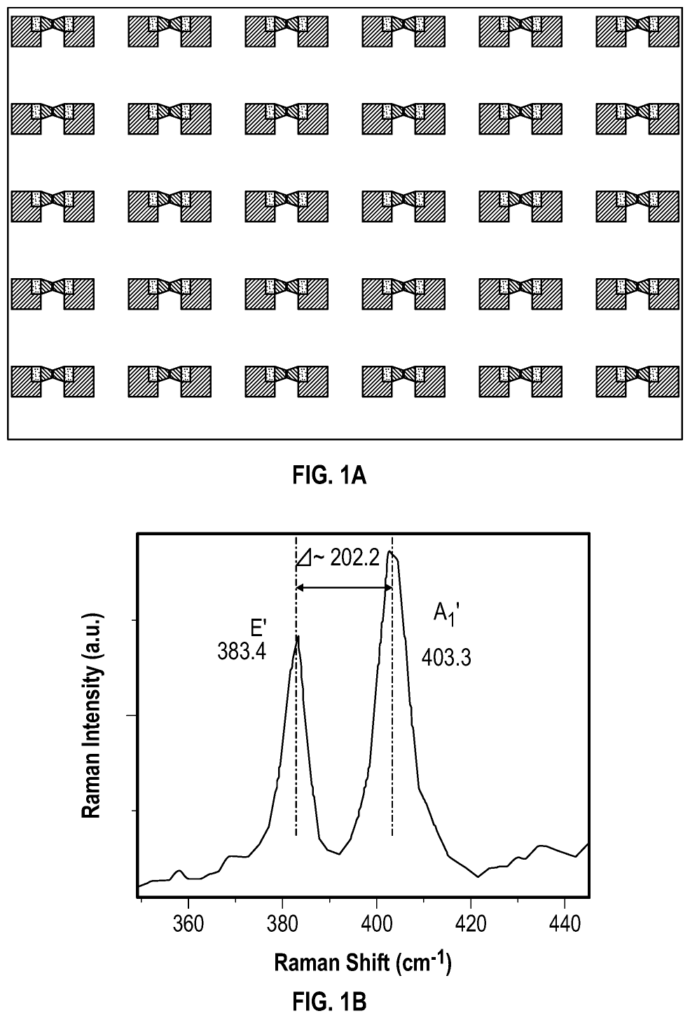

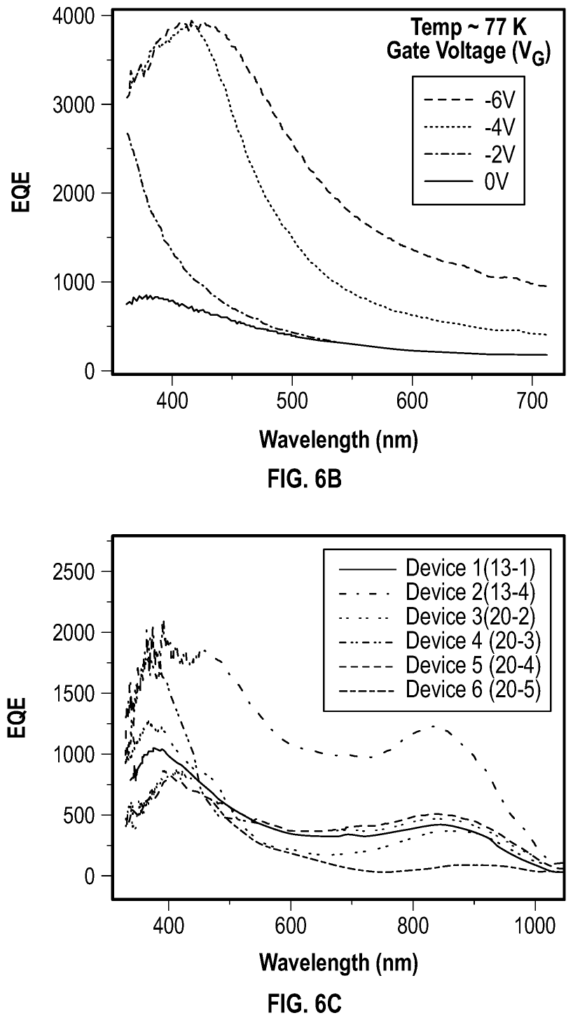

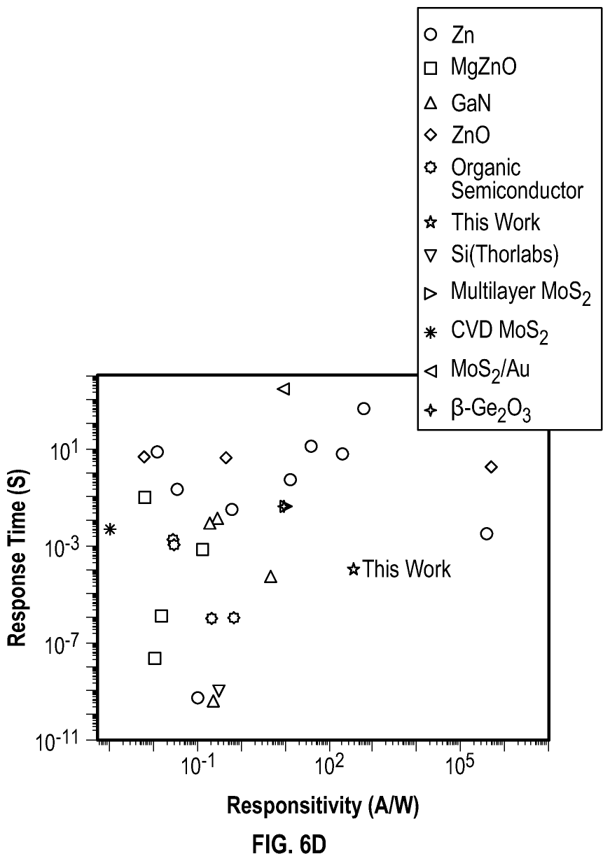

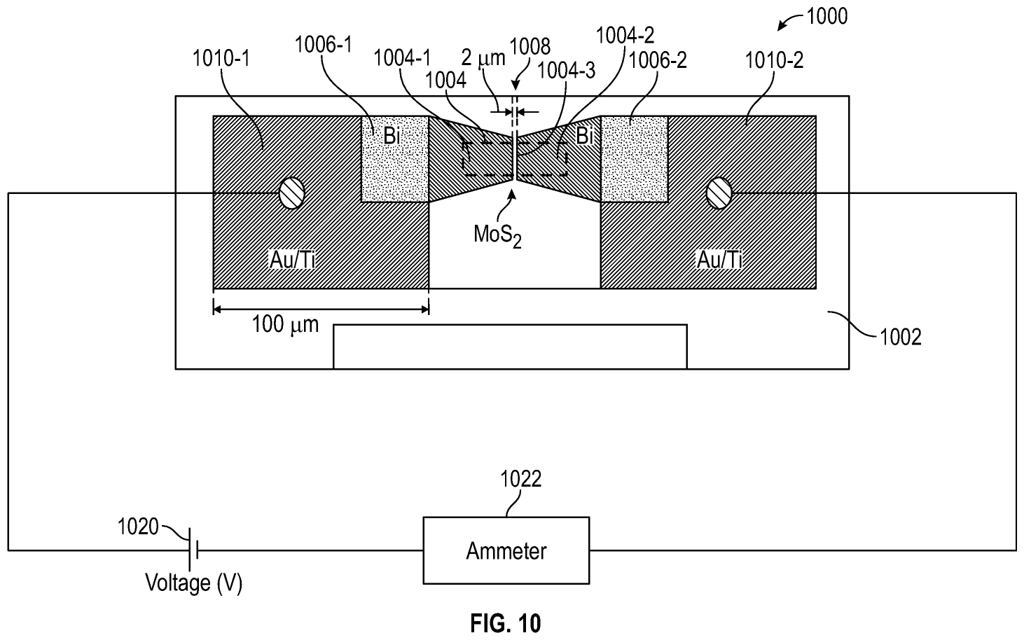

The drawings of FIGS. 1A-1B illustrate STMDS test device characteristics. FIG. 1A is an illustrative drawing showing an array of STMDS photodetector devices formed on a semiconductor substrate. FIG. 10 is an example top planer view of the example STMDS photodetector. FIG. 6A is an illustrative cross-section view of the example STMDS device of FIG. 6A. The dashed line rectangle in FIG. 10 represents a monolayer MoS₂ strip grown by sloid source chemical vapor deposition (CVD). The MoS₂ strips in FIGS. 1A-1C were prepared by optical lithography followed by oxygen plasma etching. FIG. 1B is an example graph showing Raman spectroscopy measurement from a monolayer MoS₂ of the example STMDS device of FIG. 10. The presence of two peaks (E′ and A₁′) confirming the monolayer nature of CVD grown MoS₂. The excitation laser source was 532 nm.

### Experimental Results and Discussion

TMD devices were fabricated on SiO₂/undoped-Si wafer for test use in experiments. An undoped Si wafer was selected to reduce the photogating effect, which arises due to the accumulation of the photogenerated carrier at the interface between SiO₂ and Si that gates the TMD electrostatically. [22,38,39] The surface crystal orientation of the undoped wafer was <100> and the resistivity of the wafer was >20,000 ohm-cm. A 50 nm thick SiO₂ was grown thermally, followed by growing monolayer MoS₂ by solid-source CVD technique. A detailed description of the TMD layer preparation is available in the work by Smithe et al. [40] FIG. 1A is an illustrative drawing showing an array of TMD devices on a semiconductor wafer substrate. An illustrative enlarged view of one device from the array is shown in FIG. 10. A rectangular strip of 1L MoS₂, indicted by the dashed rectangle region in FIG. 10, of size 20 μm×50 μm, was patterned using optical lithography followed by 02 plasma etching. Next, a semimetal (bismuth (Bi)) contact was formed by using optical lithography followed by electron beam (e-beam) evaporation. To avoid the formation oxidation (Bi₂O₃), a 65 nm layer of Au was deposited on top of Bi before the sample was removed from the evaporator (see FIG. 6A). The Au layer on top Bi protects it from the formation of Bi₂O₃. Moreover, it has been reported by Shen et al., that Bi₂O₃ doesn't form at the Bi/1L-MoS₂ interface during the Bi evaporation. [36]

Large square wire-bonding contact pads (size: 100 μm×100 μm) were prepared using optical lithography followed by thermal evaporation of Ti (2 nm) and Au (70 nm). The thickness dimension of different components of a device is shown in FIG. 6A. The monolayer nature of the film was confirmed by Raman spectroscopy measured at room temperature using a homemade system. Confocal micro-Raman measurements were performed after completing the device fabrication. A 100× objective lens with a numerical aperture of 0.85 was used. The excitation source was a 532 nm laser (2.33 eV) with an optical power of ˜500 W. The Raman spectrum of the sample is shown in FIG. 1B, which shows two signature peaks (E′=383.4 cm⁻¹ and A₁′=403.3 cm⁻¹) of 1L MoS₂. The gap between the Raman peak is Δ=20.2 cm⁻¹, which confirms that the sample is 1L MoS₂. [41]

To study the temperature-dependent electrical and optoelectronic properties of an STMDS sample, we mounted the samples inside a microscopy cryostat (Janis Research, ST-500) equipped with electrical feedthrough for electro-optical measurements. The cryostat was coupled with an Olympus microscope equipped with a long-working distance objective (magnification 40×). For wavelength-resolved measurements, we used a broadband light source (tungsten-halogen lamp) coupled to a double-grating monochromator (Acton Spectra Pro SP-2150i). The photocurrent was measured by employing the lock-in techniques.[42] The optical beam was modulated by an optical chopper (f=79 Hz). The optical power on the sample was determined using a well-calibrated Si p-i-n photodetector (Hamamatsu S1223).

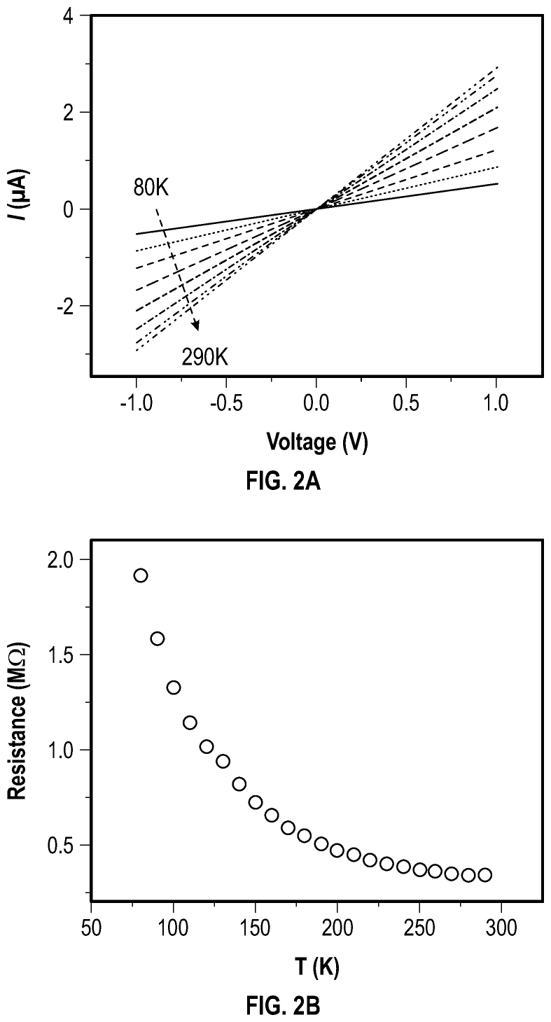

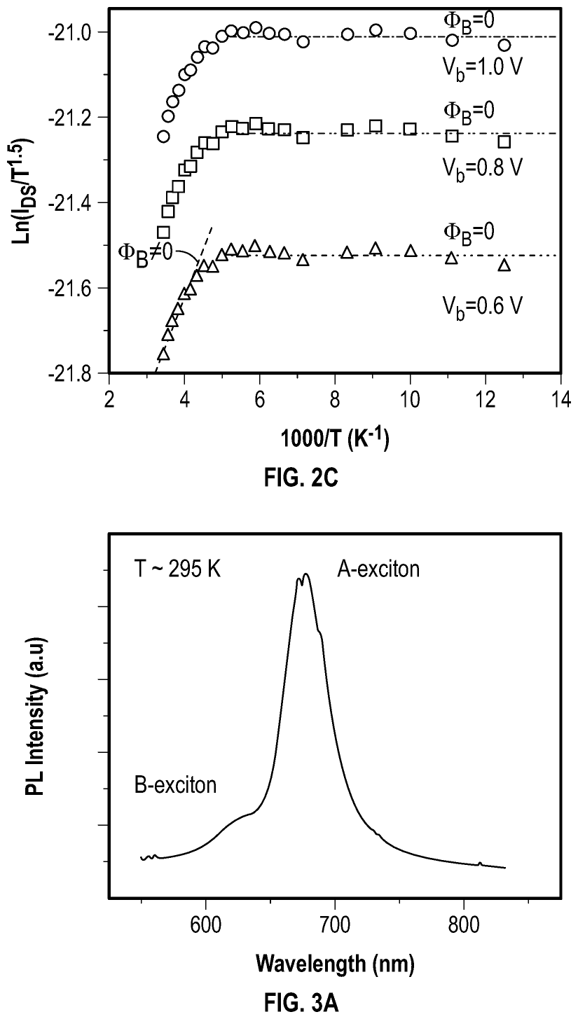

The drawings of FIGS. 2A-2C illustrate electrical transport properties of test STMDS devices FIG. 2A is an illustrative drawing showing a current-voltage (I-V) curve of a test STMDS devices at different temperature from 80 K to 290 K at every 30 K steps. The I-V curves were measured in the dark. The I-V curve shows linear behavior. FIG. 2B is an illustrative drawing showing resistance as a function of temperature for test STMDS devices. The resistance was measured from the slope of the I-V curves shown in FIG. 2A. FIG. 2C is an illustrative drawing representing determination of the Schottky barrier for test STMDS devices for different bias voltages (V_{b}). The Schottky barrier height vanishes at temperatures below 180 K. The non-zero slope in the plot (shown by blue dashed line for V_{b}=0.6 V) suggests the formation of Schottky barrier at temperatures higher than 180 K.

The electrical transport properties of the sample were measured at different temperatures from 80 K to 290 K as shown in FIG. 2A. The current was measured using a programmable source meter (Keithley 2400) connected to a current preamplifier (Stanford Research SR570). The voltage signal from the current amplifier was measured by using a digital multimeter (Keithley 2000).

A total of six test STMDS devices were studied, all of which showed similar results. The current-voltage (I-V) at different temperatures from 80 K to 290 K is shown in FIG. 2A. The inventor observed that the I-V curves demonstrate very linear behavior near the zero voltage, which suggests that the MIGS states are suppressed and the contacts are Ohmic in nature. The resistance at different temperatures from 80 K to 290 K at every 30 K step is shown in FIG. 2B. The temperature dependence of the resistance demonstrates very semiconductor-like behavior. The inventor also noted that the contact resistance also changes as we increase the temperature.

The Schottky barrier can be determined from the temperature-dependent I-V characteristics. The current (I) through an atomically thin 2D 1L MoS₂ is governed by the 2D thermionic emission equation, [43] which employs a reduced T^{1.5} power law for two-dimensional transport. [44] The test STMDS device behaves as back-to-back Schottky diode. In that case, most of the bias voltage drops in the reverse biased side. [45,46] The diode equation takes the form,

$${I}_{ds} = {A}_{2 D}^{*} {ST}^{1.5} exp [ - \frac{q}{kT} ( {Φ}_{B} - \frac{{V}_{b}}{n} ) ] \times [ 1 - exp ( - \frac{{qV}_{b}}{kT} ) ]$$

where A_{2D}* is the 2D equivalent Richardson constant, S is the contact area, n is the ideality factor, Φ_{B} is the Schottky barrier, k is the Boltzmann constant, q is the electron charge, and V_{b} is the voltage applied between the terminals. Now, it has been showed that when

$$\frac{{qV}_{b}}{kT} \geq 3 ,$$

the last term can be neglected [46] and the equation becomes,

$${I}_{ds} = {A}_{2 D}^{*} {ST}^{1.5} exp [ - \frac{q}{kT} ( {Φ}_{B} - \frac{{V}_{b}}{n} ) ] \qquad ( 1 )$$

To determine the Schottky barrier, the Arrhenius plot, i.e., ln

$$( \frac{I}{{T}^{1.5}} )$$

vs 1000/T is utilized as shown in FIG. 2C. [44,47] The slope of the plot will give

$$m = - \frac{q}{1000 k} ( {Φ}_{B} - \frac{{V}_{b}}{n} ) .$$

If the slope is plotted as a function of V_{b}, the intercept of the new plot,

$${c}_{0} = - \frac{q {Φ}_{B}}{1000 k} ,$$

will give a direct measure of the Schottky barrier height. The inventor observed that the Arrhenius plots are horizontal below 180 K for different V_{b} as shown in FIG. 2C, which means that the slopes are zero or m=0. For a plot m vs V_{b} for temperatures below 180 K, the intercept of the plot c₀, will be zero, which means Φ_{B}=0. Hence, the Schottky barrier Φ_{B} of test STMDS devices vanishes below 180 K.

Note that the horizontal line (dashed-line in FIG. 2C) separation between V_{b}=0.8 V and V_{b}=0.6 V is larger than the separation between V_{b}=0.8 V and V_{b}=1.0 V. This is originating as different I_{ds}/T^{1.5} values are plotted in a logarithmic scale.

A mechanism, similar to the mechanism proposed by Shen et al., for the vanishing of Schottky barrier in STMDS below T≤180 K was proposed by the inventor. The alignment of the Fermi level, near-zero DOS of a semimetal, and the bottom of the conduction-band minima is the principal reason for the formation of the ohmic contact at the interface.[36] For a semimetal/semiconductor interface, the Fermi level is located at the near-zero density of states (DOS) and aligned with the bottom of the conduction band. Hence, the MIGS from the conduction-band tail is heavily suppressed and the contact become Schottky barrier free.

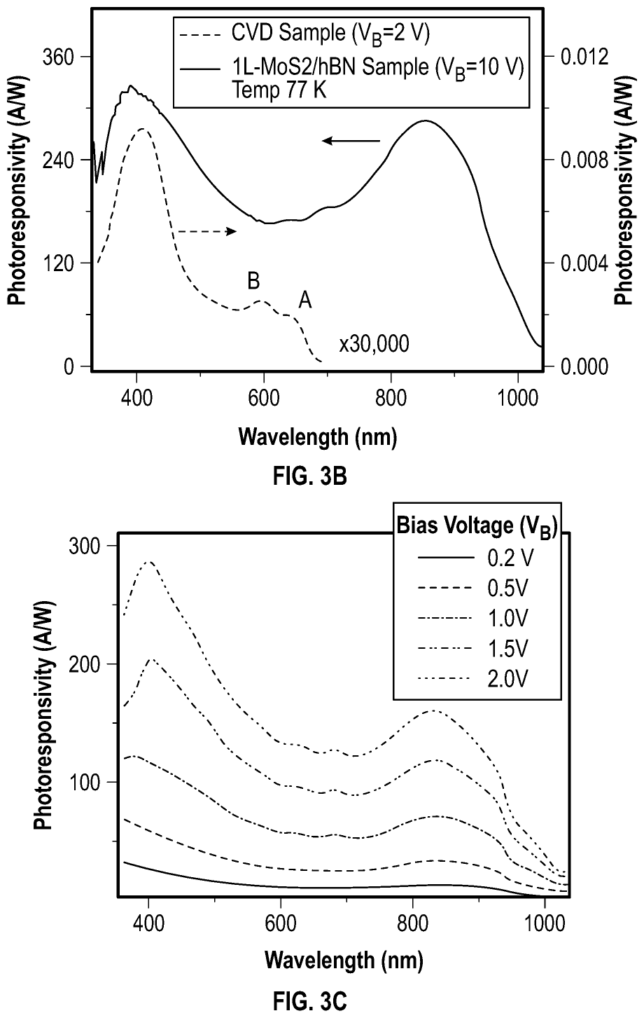

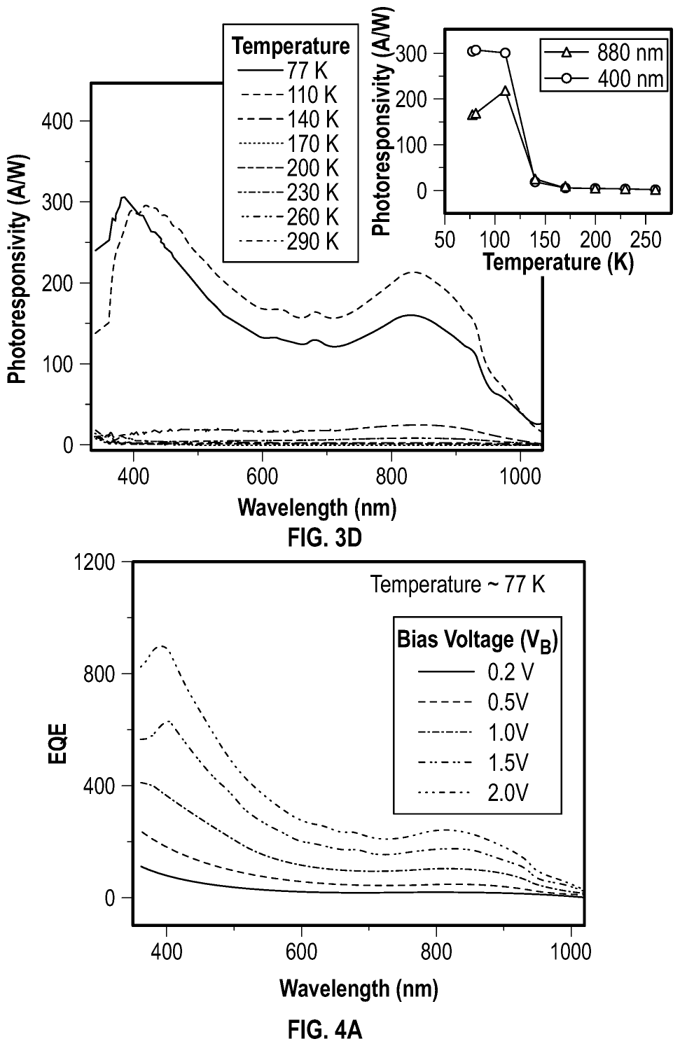

FIGS. 3A-3D show graphs of optical and optoelectrical properties of a Bi—MoS₂—Bi (STMDS) device. FIG. 3A is an illustrative graph showing photoluminescence spectrum from a test 1L MoS₂ device measured at room temperature. The excitation laser wavelength was 532 nm. Two neutral exciton peaks, A- and B-peaks, appear at 675 nm and 620 nm, respectively. FIG. 3B is an illustrative graph showing photoresponsivity (current per unit light power) of a test STMDS device at different wavelength and showing photocurrent spectroscopy from a monolayer Au—MoS₂—Au test device on a glass substrate encapsulated by hBN. The photoresponsivity in the Au-1L MoS₂—Au is 30,000 smaller than that from our Bi—MoS₂—Bi sample. Two peaks at 650 nm and 590 nm in the photoresponsivity spectrum of Au-1L MoS₂—Au sample are due to the A- and B-excitons and are marked by A and B, respectively. FIG. 3C is an illustrative graph showing photoresponsivity of a test STMDS device at different bias voltages measured at 77 K. Linear behavior increases with increased bias voltage. FIG. 3D is an illustrative graph showing photoresponsivity of a test STMDS device at different temperatures. It can be seen that the photoresponsivity vanishes as the temperature is increased. The inset to FIG. 3D shows amplitude of the photocurrent peak in the infrared region (wavelength ˜880 nm) and at the UV edge (˜400 nm) at different temperatures.

The optical and optoelectronic properties of a test TSMDS device are shown in FIGS. 3A-3D. Photoluminescence spectrum was taken from the sample at room temperature by exciting using a 532 nm green laser and is shown in FIG. 3A. Two peaks are shown at 675 nm and 620 nm, which correspond to the A- and B-excitons in 1L MoS₂, [22,48,49] confirming that the test TMD devices are of monolayer nature.

Photocurrent was measured using two different types of optical sources; (i) lasers (wavelength 405 nm and 650 nm) and (ii) a broadband tungsten-halogen thermal source. In atomically thin 2D TMD-based photodetectors, the photocurrent originates from two main mechanisms: (i) the photoconductive effect, where the photogenerated electron-hole pairs increase the carrier density and the electrical conductivity; and (ii) the photogating effect, where the photogenerated carriers filled the localized trap states and cause a shift of the Fermi energy. [50-56] The photoconductive mechanisms in the test STMDS devices were probed by measuring photocurrent with varying light power, bias voltages, and laser pulse width. The measurements show that photogating is the dominant mechanism in the devices.

To understand the photocurrent mechanism, the wavelength-resolved photoresponsivity (photocurrent per unit power of lights), Rdλ, of the sample was determined for a wide range of wavelengths from the edge of UV (λ˜380 nm) to near infrared (λ˜1050 nm). FIG. 3B shows the photoresponsivity of a test STMDS device measured at 77 K. The light power on the sample was calibrated by a Si p-i-n photodetector (Hamamatsu S1223). The scanning photocurrent image of the sample was measured to map the region of photocurrent contribution and found zero photocurrent outside our sample.

Three significant features were observed. First, one peak was observed at 380 nm. The inventor attributed this observed peak to the van Hove singularity exciton, which also causes the highest absorption of photons. [22] Second, the photocurrent peaks due to A- and B-excitons were not visible in the spectrum. The inventor attributed the absence these peaks to the photogating effect which is the main mechanism of the photocurrent generation in the test STMDS devices. There are two competing photocurrents in our devices. A first photocurrent is originating from the exciton dissociations [22] and a second photocurrent is originating from the photogating. [57] Since the photocurrent due to photogating is several order magnitudes higher than the photocurrent due to exciton dissociation, the signatures of A- and B-exciton peaks do not appear in the photocurrent spectrum.

Peaks were observed in the photocurrent spectrum due to the A- and B-excitons for alternative STMDS devices that were grown following the similar solid source CVD method and were prepared on a quartz crystal substrate. The alternative STMDS device were electrically connected by Ag/Au metal layers. A quartz substrate was used to remove the photogating effect completely. [41] Since the photogating effect is absent in the alternate test SMTMDS device prepared on a quartz substrate, exciton dissociation is the dominant photocurrent mechanism and the exciton related peaks appear in the photocurrent spectrum of the Au/Ag/1L-MoS₂/Ag/Au devices (Also, the photoresponsivity in Au/Ag/1L-MoS₂/Ag/Au devices was measured and determined to be six orders of magnitude lower than that in MoS₂/Bi devices.

A photoresponsivity peak also was observed in infrared region (˜880 nm at 77 K). To understand the origin of the infrared peak, the absorption and photocurrent in the infrared regime of an alternative Ag/Au/1l-MoS₂/Ag/Au device was studied. If the photogating is absent in a device, the photocurrent is proportional to the absorption coefficient. Hence, the photoresponsivity spectrum in the alternative Au/Ag/1L-MoS₂/Ag/Au sample on a quartz substrate is proportional to the absorption spectrum. A zero photocurrent was measured in those Au/Ag/1L-MoS₂/Ag/Au devices for wavelengths 700 nm-1100 nm, which suggests that the infrared peak in the Bi/1L-MoS₂/Bi sample is not due to any intrinsic properties or defects in the CVD grown 1L-MoS₂. The infrared peak is originating due to the silicon-MoS₂ heterojunction. Indeed, the Silicon photodiode demonstrate a responsivity peak around 900 nm. [58] Moreover, similar infrared peak in the photocurrent detectivity has been reported for graphene-Si heterojunction. [10]

Following are details of experimental results supporting the photogating mechanism in STMDS devices. To compare the photocurrent spectrum with a conventional micro-exfoliated TMDs, a study also was performed of the photocurrent spectroscopy of a high-quality 1L MoS₂ sample encapsulated by a thin hexagonal boron nitride (hBN) flake as shown in the FIG. 3B (red line). The samples were fabricated on a glass substrate using the dry transfer technique and were electrically connected to a pre-patterned Au electrode. For detailed results on fabrication and photocurrent spectroscopy of exfoliated 1L MoS₂, reference is made to publications by Benson et al.[59] The right axis in FIG. 3B presents the photoresponsivity from the 1L MoS₂ sample. The photoresponsivity in the test STMDS devices is ˜30,000 larger than that from an exfoliated 1L-MoS₂ sample, which suggests extraordinarily high photocurrent in STMDS device. The two peaks at 650 nm and 590 nm in the photoresponsivity spectrum of 1L-MoS₂/hBN sample in FIG. 3B are due to A- and B-excitons.

To understand the electric field-dependent photocurrent, tests were performed for photocurrent spectrums for different bias voltages as shown in FIG. 3C, which shows that photocurrent increases linearly with increase the bias voltage. FIG. 3D presents the temperature dependence property of the photocurrent spectrum at a wide range of temperatures from 80 K to 298 K. FIG. 3D shows that photocurrent decreases sharply at temperatures higher than 120 K and almost disappears near room temperature (T≥250 K).

To determine the temperature-dependent behavior of photocurrent, the amplitude of the photocurrent peak in the infrared (˜880 nm) and UV edge (˜400 nm) was measured at different temperatures as shown in the inset of FIG. 3D. The photocurrent increases with increased temperature from 77 K and peaked at ˜110 K. Similar behavior of temperature-dependent photocurrent was observed in MoS₂ [60] and natural van der Waals heterostructure, Franckeite. [42]

The variation of photocurrent due to temperature is originated from a two main factors: (i) change of contact resistance, and (ii) trap states. At low temperature (T≤110 K), the trap states originate from valence-band-contributed MIGS and the numbers of photogenerated carriers are higher than the number of trap states (also acting as the recombination centers). As the temperature increases from 77 K (77 K≤T≤110 K), the contact resistance decreases, which increases the photocurrent. At temperature higher than 110 K (T≥110), the photocurrent reduces for two reasons; (i) localized defect states become extended defects in 1L-MoS₂ [61] and (ii) the number of photogenerated carriers become smaller than the number of trap states. [60]

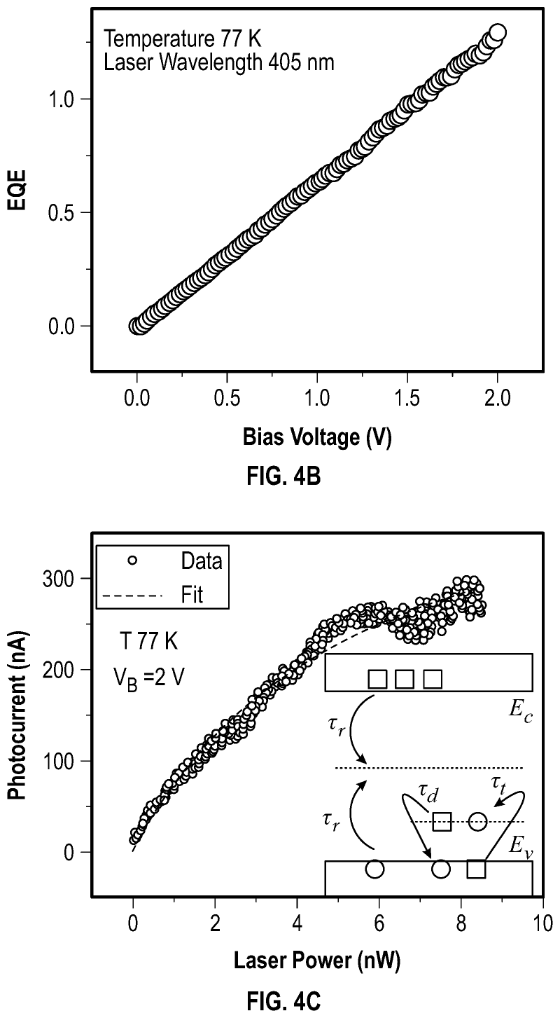

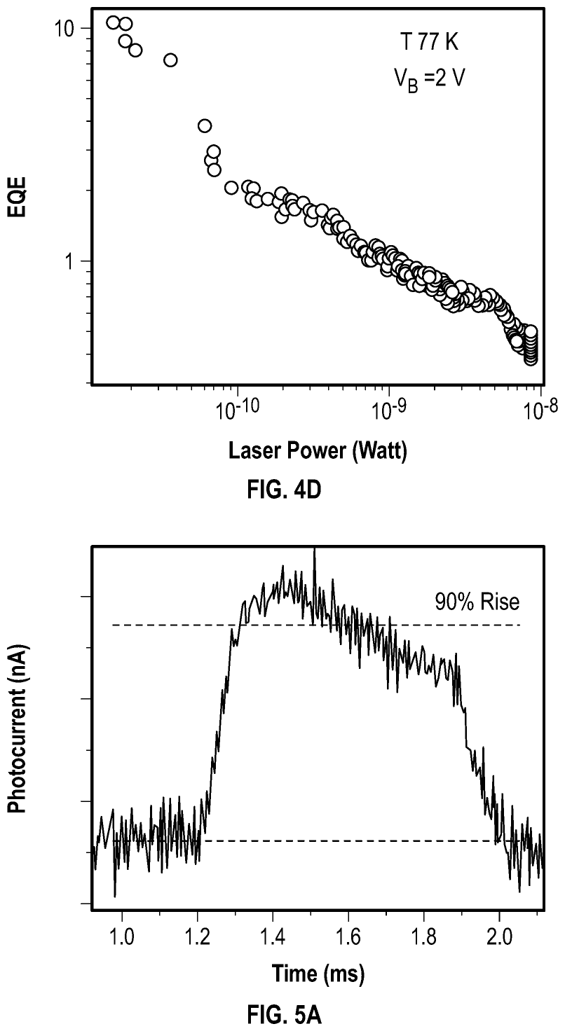

The graphs of FIGS. 4A-4D show measurements of external quantum efficiency (EQE), which is defined as the number of electrons stimulated to a current-conducting state for each one photon incident upon a STMDS layer of a photodetector device. Optical photon energy incident upon the STMDS device excites electrons that can be detected by measuring current, consisting of the excited electrons, flowing between electric contacts on opposite sides of the STMDS layer of the photodetector device. A higher EQE means that more electrons are available per incident photon to conduct current. Stated differently, EQE is a measure of photoresponsivity. The higher the EQE, the higher the photoresponsivity. FIG. 4A is an illustrative graph showing EQE of a test STMDS device at for two terminal device with different bias voltages and different wavelengths. The graph in FIG. 4A indicates that the test STMDS devices exhibit photoresponsivity in an optical wavelength range between from about ˜380 nm, which is UV light, to about 1,000 nm. The electronic band structure of MoS₂ suggest that STMDS devices device will also be sensitive in the range 250 nm-380 nm. Because of the limitation of the experimental setup below 380 nm, the inventor could not measure the photoresponsivity below 280 nm”. The highest efficiency was observed for UV photons at ˜400 nm. The graph in FIG. 4A also shows that EQE increases with bias voltage. In the EQE calculation, absorption coefficient is not included in the photon absorption efficiency. If the photon absorption coefficient is included, then the EQE will be an order of magnitude higher. FIG. 4B is an illustrative graph showing measurement of EQE as a function of bias voltage. A 405 nm laser was used for the measurement of EQE versus voltage bias. A high power laser was used to improve the signal, which is why EQE is lower for this measurement. FIG. 4C is an illustrative graph that shows photocurrent as a function of a 405 nm laser power measured at 77 K. The bias voltage was 2 V. The inset in FIG. 4C shows a simplified energy band diagram that shows the main features of the charge trapping and de-trapping model. The valence band trail is approximated by a discrete distribution of hole traps with density Dₜ (occupation of traps pₜ). The holes are trapping into the states and de-trapping out of the sates with a rate 1/τₜ and 1/τ_{d}, respectively. FIG. 4D is an illustrative graph showing EQE as a function of the laser power. The EQE decreases logarithmically as we increase the power, which is clear sign that the high EQE is originating from the photogating effect as describe above.

The external quantum efficiency (EQE), which is defined as a ratio of the number of electrons in the external circuit to the number of incident photons was calculated to determine the photodetector performance. FIG. 4A presents EQE for different bias voltages (V_{b}), which is connected to photoresponsivity R_{λ}, by

$$EQE = \frac{{R}_{λ}}{λ} \times 1240 ,$$

where R_{λ} is the responsivity in A/W, and λ is the wavelength in nm. We observed an EQE of 1000 or 10⁵% at 77 K for a bias of 2V. Note that high photoresponsivity was reported for a 1L MoS₂ phototransistor sample before, where the samples are gated by a very large gate voltage. [57] The highest EQE values are observed for a two-terminal device without requiring any gate voltage, which can be beneficial for many imaging applications. The large EQE indicates that the test STMDS devices can act as sensitive broadband photodetectors.

Photoresponsivity behavior of STMDS devices as a function of bias voltage and laser power were measured to understand the origin of this extraordinary EQE. FIG. 4B shows EQE as a function of bias voltage at 77 K while the device was illuminated by a 405 nm laser. The lower EQE value in FIG. 4B is due to the high laser power used in this measurement. The linear behavior of EQE as a function of the bias voltage, suggests that the gain mechanism is related to the photogating of the test STMDS device. The vanishing of photocurrent or EQE at V_{b}=0 indicates that photovoltaic effect, which may occur for a semimetal/TMD interface, [62] does not contribute to any photocurrent in the test STMDS devices. The absence of the photovoltaic effect is attributable to the absence of the Schottky barrier at the semimetal/MoS₂ interface. A laser power-dependent photocurrent study as shown in FIG. 4C, to further determine the photoresponse mechanism.

Following the earlier literature, [50,56,63] the laser power-dependent data was analyzed using the Hornbeck-Haynes model. [64,65] It has been demonstrated that the structural defects and disorder cause the band tail states or shallow trap states near the valence band and conduction band. [66-68] In addition to the shallow trap states, there also exists deep recombination centers, also known as midgap states, which cause nonradiative (Shockley-Read-Hall-type) recombination. [50,56] The physical mechanism is shown schematically in the inset of FIG. 4C. For the n-doped 1L-MoS₂, only the hole traps near the valence band are relevant. The trapping and de-trapping of the hole states occur with rate 1/τₜ and 1/τ_{d}, respectively. If the filling of the trap states by photogenerated carrier cause the electrostatic gating, it will shift the Fermi energy and increase the electrical conduction. Using this model, the photogated current is given by,

$${I}_{PC} = A \frac{1}{1 + \frac{B}{{P}_{D}}}$$

The two parameters A and B are given by

$$A = \frac{{D}_{t} {C}_{g} {C}_{q}}{e ( {C}_{g} + {C}_{q} )} \frac{{dV}_{b}}{{dV}_{g}} ; B = \frac{{D}_{t} hc}{η λ {τ}_{r}} ( \frac{{τ}_{t}}{{τ}_{d}} )$$

where Dₜ is the density of the localized traps, Cdg is the geometrical capacitance, C_{q} is the quantum capacitance, V_{g} is the gate voltage, e is the electron charge, h is the Planck constant, λ is the excitation laser wavelength, and η is the absorption coefficient of 1-MoS₂. The laser power-dependent photocurrent is fitted with this model using A and B as the fitting parameter as shown in FIG. 4C. Excellent fitting of the experimental data was obtained, confirming that photogating is the main mechanism in our devices. Since an undoped substrate was used, we could not determine the dV_{b}/dV_{g} and the density of traps using the fitting parameters. FIG. 4D presents EQE as a function of laser power measured at 77 K. Note that EQE decreases logarithmically as a function of laser power, which is also a signature of the photogating effect. [57]

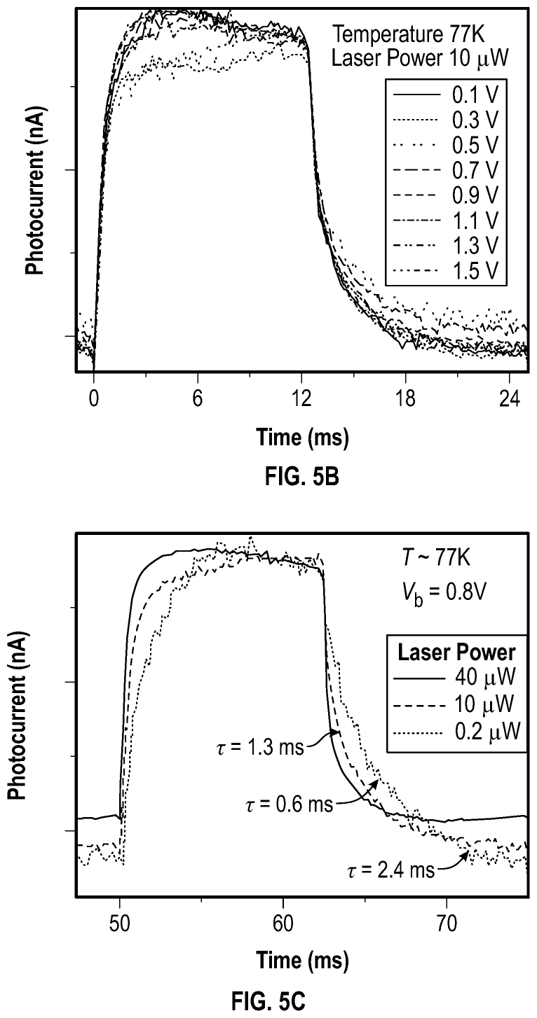

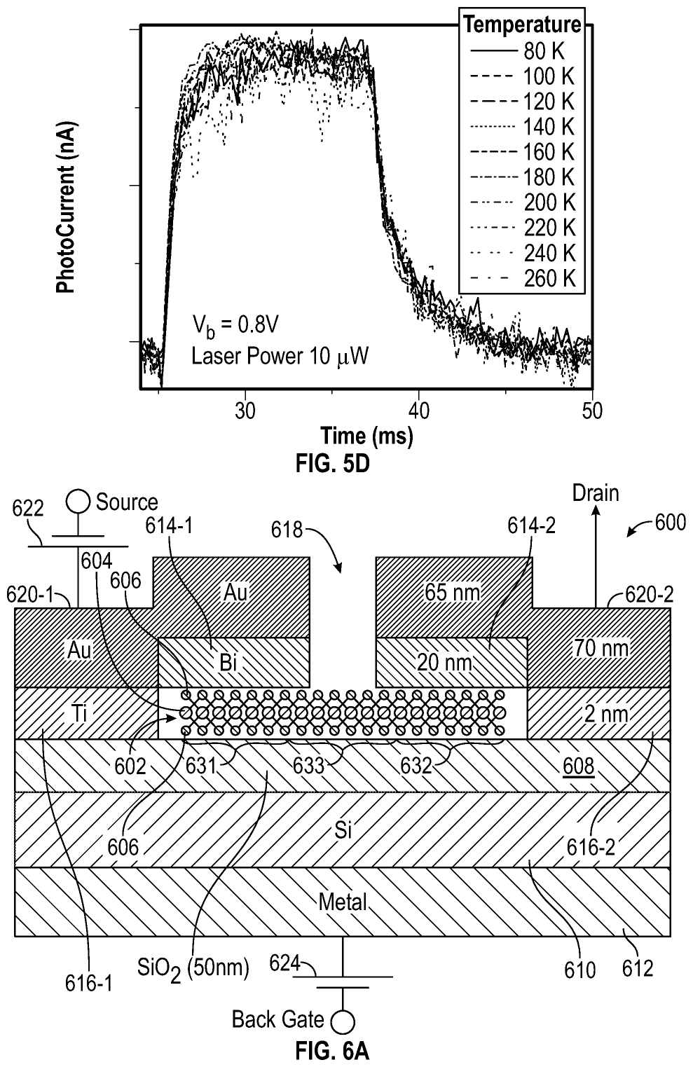

The graphs of FIGS. 5A-5D show time response of a test STMDS device. The time responses were measured at 77K. FIG. 5A is an illustrative graph showing time response of a test STMDS device for a single laser pulse using a 405 nm laser modulated by a mechanical chopper (f˜700 Hz). The graph of FIG. 5A shows a 90% rise time is 0.1 ms. FIG. 5B is an illustrative graph showing a time response of the device for different V_{b} voltages measured for a 10 μW laser power. The graph of FIG. 5B shows no correlations between the decay time after the cessation of the laser and the bias voltage. FIG. 5C is an illustrative graph showing time response as a function of different laser power. The graph of FIG. 5C shows that the measured decay time increases with increased laser power. The determined decay time is marked next to the lines. FIG. 5D is an illustrative graph showing time response as a function of temperature. The graph of FIG. 5D shows no correlations between the decay time after the cessation of the laser and the temperature.

FIGS. 5A-5D show the time response of the test STMDS devices at 77 K The devices were illuminated by a chopped laser (ƒ=700 Hz) and the signal was measured by an oscilloscope. The bias voltage of the devices was 2V. The time response of the photocurrent for a single pulse is shown in FIG. 5A. A 90% rise time of the photocurrent is 0.1 ms, i.e., the frequency response of the current devices is ˜10 kHz as shown in FIG. 5A. By measuring photocurrent for a long time after terminating the laser illumination, the presence of persistent photocurrent in the test STMDS devices was not observed.

To understand the decay time of the photocurrent in the dark, time response as a function of bias voltage V_{b}, laser power, and temperature T, were studied as shown in FIGS. 5B-5D. The decay time in the dark does not depend on temperature and the bias voltage as shown in FIG. 5B and FIG. 5D, respectively. On the other hand, the decay of the photocurrent after cessation of laser excitation depends strongly on the laser power impinging on the device as shown in FIG. 5C. The decay time was measured by fitting an exponential decay function (I=I₀e^{-t/τ}, where t is the time and τ is the decay constant). The decay constant decreases monotonically as we increase the laser power. This is also a signature of the photogating effect. At a lower intensity, the trap states remain unsaturated and dominate the photocurrent decay after the cessation of laser excitation. With increasing laser power, the trap states get saturated and don't dominate the photocurrent decay resulting in a much lower (i.e., faster) decay time. Similar property of decay time as a function of control gate voltage was reported for a 1L MoS₂ phototransistor. [55] Hence, the results consistently suggest that the high EQE observed in the test STMDS devices are originating from the photogating effect in 1L MoS₂ or at the interface between 1L MoS₂ and the oxide layer. The time response of the sample using a red laser (˜650 nm) also was investigated, and the results showed that the 90% rise time of the photocurrent is 0.4 ms and the photocurrent decay become slower as the laser power is increased. Thus, the device has a broadband property and can be used in the visible-near infrared region.

An alternative TMD photodetector device structure includes a Bi/1L-MoS₂/Au device so that one contact is Ohmic and the other contact is Schottky contact.

To tune the EQE by using electrostatic gating, photocurrent EQE of the test STMDS devices was measured by applying a back-gate voltage. A silver conductive paint or silver colloidal suspension on the back side of the Si substrate was used to prepare a metallic gate. The circuit configuration of a test STMDS device 600 with a back-gate is shown in FIG. 6A, which is effectively working as a phototransistor. The STMDS device 600 includes a 1L TMD layer 602 that includes an inner molybdenum (Mo) layer 604 and outer sulfide (S₂) layers 606. The TMD layer 602 is formed on an insulating silicon dioxide (SiO₂) layer 608. The insulator layer 608 is formed on an undoped (intrinsic) silicon layer 610. The undoped silicon layer is located upon a conductor layer 612 comprising a metal material. The undoped silicon layer 610 is sandwiched between the insulator layer 608 and the conductor layer 612. The absence of dopant in the undoped silicon means that dopant charge carriers are unavailable to be excited by photons incident upon the 1L TMD. Thus, current measured between source and drain terminals of the device is a result of electrons excited by photons incident upon the 1L TMD and that there is no current contribution from charge carriers excited from the silicon layer 610. The undoped silicon prevents current flow between the conductor layer 612 and the insulating layer 608. First and second Bismuth semimetal contacts 614-1, 614-2 are formed on and overlay a corresponding first portion 631 and a corresponding second portion 632 of the TMD layer 602 that are on opposite sides of an optical channel 618. The first and second Bi semimetal contacts 614-1, 614-2 are patterned to create a substantially vertical optical channel 618 between them extending to and terminating at a third portion 633 of the TMD layer 602, located between the first and second portions 631, 632, that is not overlain by semimetal, metal or wetting material. The channel 618 provides a pathway opening though which photons can pass to access to the TMD layer 602. The optical channel 618 can have a protecting thin layer (not shown), which for example, can comprise atomically thin hBN, or SiO2, SiNx. First and second wetting layers 616-1, 616-2 are formed on and overlay portions of the insulator layer 608 adjacent to outer edges of the first and second portions 631, 632 of the STMDS layer 602 on opposite sides of the opening 618. In an example embodiment, the wetting layer comprises Ti. First and second metal contacts 620-1, 620-2 are formed on opposite sides of the opening 618. In an example embodiment, the metal contacts 620-1, 620-2 comprise Au. A first metal contact overlays the first semimetal contact 614-1 and the first wetting layer 616-1. A second metal contact 620-2 overlays the second semimetal contact 614-2 and the second wetting layer 616-2. The first and second semimetal contacts 614-1, 614-2 and the first and second wetting layers 616-1, 616-2 electrically isolate the first and second metal contacts 620-1, 620-1 from the TMD layer 602.

In an example STMDS device, the first metal contact 620-1 is coupled to act as a source terminal. The second metal contact 620-2 is coupled to act as a drain terminal. The conductor layer 612 is coupled to act as a back gate terminal. A source voltage 622 is provided to the source terminal 620-1. A back gate voltage 624 is provided to the back gate terminal 612.

The circuit configuration of FIG. 6A was used to study the electrostatic gating effect on photocurrent. The application of a back-gate voltage changes the doping concentration near the sample, which modifies the photoresponsivity. FIG. 4B shows that EQE increases as we apply a negative back gate voltage. The application of a negative gate voltage lowers the Fermi level, which makes more trap states available to the photogenerated carrier and increases EQE. EQE can be enhanced significantly by electrostatically doping the samples as shown in FIG. 6B. The illustrative graph of FIG. 6B shows EQE of the device for back-gate voltages 0V, −2V, −4V, and −6V. The EQE was enhanced by 4 times (EQE_{Max}˜4000) when the back-gate voltage is −6 V. The graph in FIG. 6A, like the graph in FIG. 4A, indicates that the test STMDS devices exhibit photoresponsivity between from the UV range starting at about ˜380 nm about 1,000 nm. Significantly, photoresponsivity is increased with increased back-gate voltage, without a corresponding increase in electrical noise. This also confirms that the high EQE observed in our devices is due to photogating effect.

The graph of FIG. 6C shows external quantum efficiency plots for six different test STMDS devices to demonstrate the device performance variation. All the measurements were conducted under the same optical and electrical settings at 77 K. The average EQE values for all devices at 400 nm is 1200±430. Hence the maximum responsivity at λ˜400 nm varies by ˜50% from the average values as shown in FIG. 6C.

The test STMDS devices work the best at approximately 400 nm wavelength photon, the following discusses the figure of merits of our photodetector compared to other solid-state UV photodetectors reported in the literature. The responsivity and the response time of different solid-state UV photodetectors are shown in FIG. 6B, which are obtained from the review article by Alaie et al. [69] The responsivity and the response-time data for multilayer MoS₂/Au, CVD MoS₂/Au and exfoliated 1L, exfoliate MoS₂/Au, and PGe203 devices were reported by Zhang et al., [70] Yore et al, [41] Furchi et la. [50], and Arora et al., [71] respectively. FIG. 6B clearly shows that our semimetal-TMD based UV photodetector demonstrates superior performance. Hence, semimetal-TMD-semimetal photodetector possesses a true potential for next-generation solid-state photodetector.

### Example Embodiments

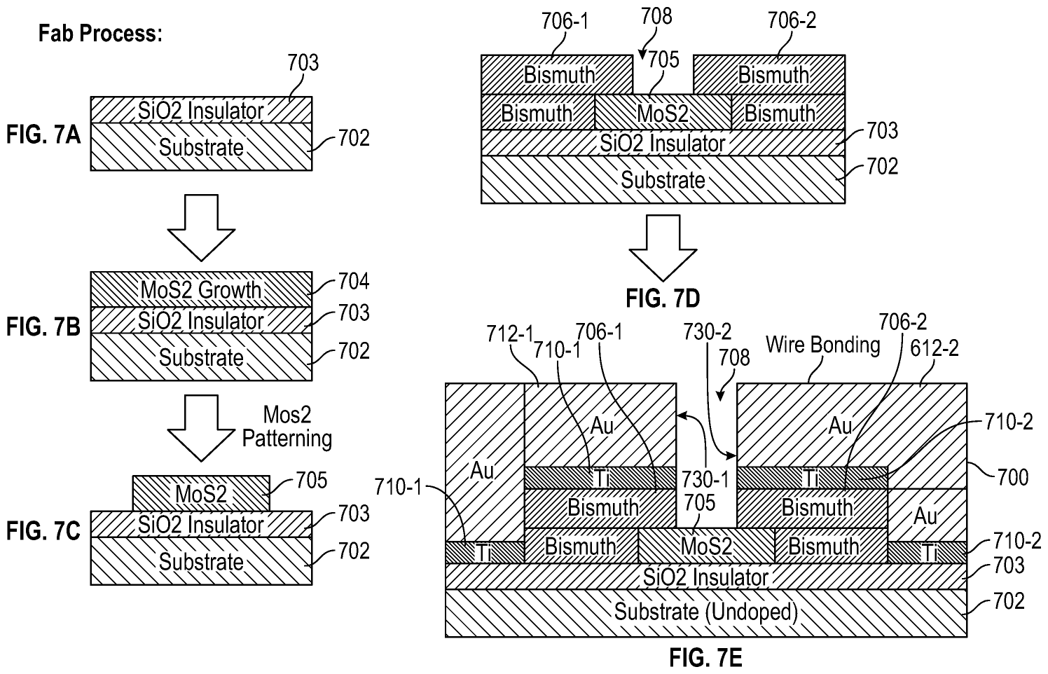

FIGS. 7A-7E is an illustrative drawing showing an example process to manufacture a first example photodetector 700, shown in cross-section view, that includes two electrical terminals in accordance with some embodiments. FIG. 7A shows an example first manufacturing step in which an undoped silicon substrate layer 702 is provided. In an example embodiment, the silicon substrate layer 702 includes an insulator layer 703. In an example embodiment, the insulator layer 703 includes a silicon dioxide (SiO₂). FIG. 7B shows an example second manufacturing step in which a monolayer TMD 704 is deposited to overlay a portion of the insulator layer 703. In the example embodiment the monolayer TMD 704 comprises monolayer MoS₂. FIG. 7C shows an example third manufacturing step in which the monolayer TMD 704 is patterned, through etching for example, to form a monolayer TMD island 705 upon the insulator layer 703. FIG. 7D shows an example third manufacturing step in which first and second semimetal contacts 706-1, 706-2 are deposited upon separate regions of the monolayer TMD island region 705 and surrounding portions of the top surface of the insulator layer 703, while defining portions of sidewalls 730-1, 730-2 that define a substantially vertical optical channel 708 through which photons can pass to reach a portion of the monolayer TMD island region 705 that is free of overlaying semimetal material. The optical channel 708 can have a protecting thin layer (not shown), which for example, can comprise atomically thin hBN, or SiO₂, SiNx. The optical opening 708 allows passage of photons to impact upon an exposed portion of the monolayer TMD island region 705. In an example embodiment, the semimetal comprises Bismuth. FIG. 7E shows an example fifth manufacturing step in which first and second adhesion contacts 710-1, 710-2, also referred to as a wetting layer or adhesive layer, are deposited upon the respective first and second semimetal contacts 706-1, 706-2 and upon surrounding portions of the insulator layer 703, while leaving the opening 708 free to permit passage of photons to the exposed portion of the monolayer TMD island region 705. In an example embodiment, the adhesion contacts 710-1, 710-2 comprise titanium (Ti). Also, in the example fifth manufacturing step, first and second metal conductor contacts 712-1, 712-2 are deposited upon the respective first and second adhesion layer contacts 710-1, 710-2 and surrounding portions of the insulator layer 703. In an example embodiment, the metal conductor contact comprises gold (Au). Additionally, the example fifth manufacturing step, first and second wire bonds 716-1, 716-2 are electrically coupled to the first and second metal contacts 712-1, 712-2.

A first sidewall 730-1 includes a portion of the first semimetal contact 706-1, a portion of the first adhesion contact 710-1, and a portion of the first metal contact 712-1. A second sidewall 730-2 includes a portion of the second semimetal contact 706-2, a portion of the second adhesion contact 710-2, and a portion of the second metal contact 712-2. The first and second sidewalls 730-1, 730-2 define the optical channel opening 708 that extends through the electrical contact layers to the TMD 704 layer and though which photons can pass to reach and be incident upon the TMD layer 704.

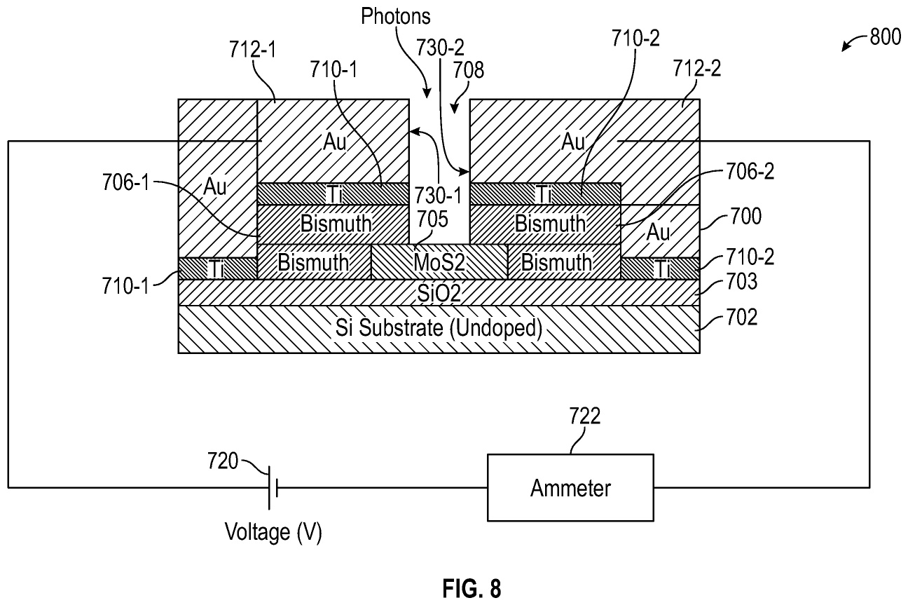

FIG. 8 is an illustrative drawing showing the cross-section view of the first example photodetector 700 of FIG. 7 electrically coupled as a two-terminal device. A bias voltage source 718 imparts a voltage V between the first and second metal contacts. 712-1, 712-2. A current measurement device 722 is coupled to measure current between the first and second metal contacts 712-1, 712-2, which act as first and second electrical terminals. In operation, photons pass through the optical channel opening 708 and are incident upon the TMD layer 704. The photons cause electrons and holes to be released by the monolayer TMD. Positively charged holes that become trapped between the monolayer TMD region 704 and the insulator layer 703 form a conduction region 724 that conducts current between the first and second metal contacts 712-1, 712-2, via the first and second semimetal contacts 706-1, 706-2.

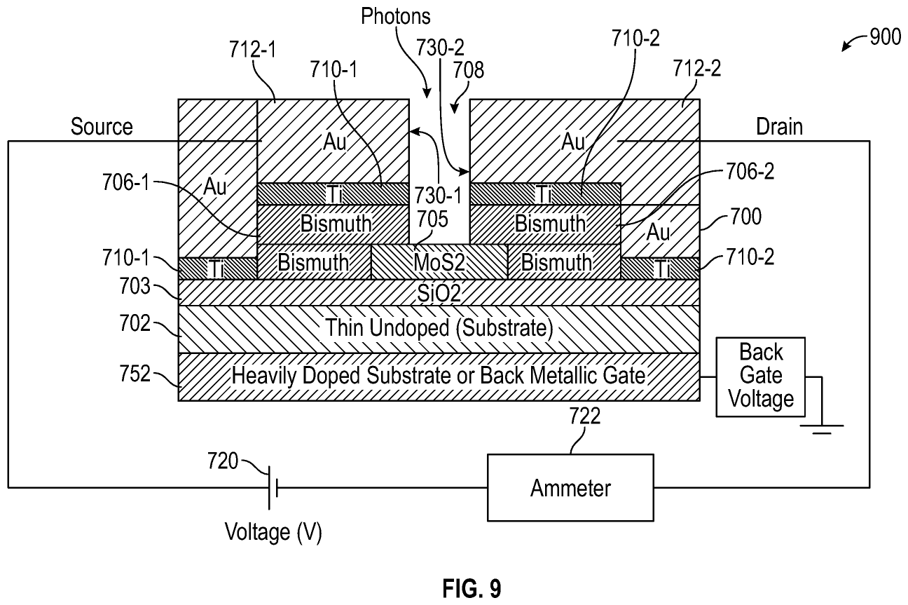

FIG. 9 is an illustrative drawing showing a cross-section view of a second example photodetector 750 that includes three electrical terminals in accordance with some embodiments. The overall structures of the first and second example photodetectors 700, 750 are similar. For economy of disclosure, only certain differences will be explained with respect to the example second photodetector 750. The undoped semiconductor layer 702 (e.g., undoped silicon) is thin. In an example photodetector, the undoped silicon layer has a thickness in a range between 10 nm and 100 nm and rests upon a back gate conductive layer 752. The back gate conductive layer 752 can be formed of a heavily doped semiconductor substrate (e.g., silicon) or can be metallic so as to act as a back gate terminal. A doping concentration in a heavily doped semiconductor back gate 752 is about 10¹⁹/cm⁻³, resistivity 0.001-.005 ohm·cm. A gate voltage V_{G} is imparted to the back gate terminal 752. Using this three-terminal structure, the EQE value can be tuned to improve over the two-terminal EQE values by many times. By applying a back gate to the heavily doped substrate, the availability of the trap states inside the CVD TMD or at the interface between the TMD and oxide layer can be controlled. If there are more trap states available, then the EQE will be much higher than if there are fewer trap states available. Hence, a three-terminal photodetector will be more highly tunable. By way of comparison, in a regular transistor device, a gate voltage applied directly to the doped substrate changes a resistance between the source and drain.

FIG. 10 is an example top planer view of an example photodetector 1000 in accordance with some embodiments. A monolayer TMD indicated by rectangular dashed lines 1004, is deposited upon the insulator layer 1002. An example TMD comprises MoS₂. In an example embodiment, the monolayer TMD layer 1004 overlays the insulator layer 1002, which overlays an undoped silicon layer (not shown). A first semimetal contact 1006-1 overlays a first portion 1004-1 of the TMD layer 1004. A second semimetal contact 1006-2 overlays a second portion 1004-2 of the TMD layer 1004. Example first and second semimetal contacts 1006-1, 1006-2 comprise Bismuth. The first and second TDM layer portions 1004-1, 1004-2 have a large enough surface area to provide low contact resistance between the monolayer TMD 1004 and the semimetal contacts 1006-1, 1006-2. A third portion 1004-3 of the TMD layer 1004 is located between the first and second TDM layer portions 1004-1, 1004-2, opposite an optical channel opening 1008 between the first semimetal contact 1006-1 and the second semimetal contact 1006-2, through which photons can pass to reach the TDM layer 1002. Thus, photons can reach the third TMD layer portion 1004-3 through the channel opening 1008. In an example photodetector 1000, the third TMD layer portion 1004-3 has a length of about 2 microns and width of about 20 microns. A first terminal comprising the first adhesion contact 1010-1 is formed overlaying a portion of the first semimetal contact 1006-1. A second terminal comprising a second adhesion contact 1010-2 comprising a second metal is formed overlaying a portion of the second semimetal contact 1006-2. Example first and second adhesion contacts comprise AU/Ti. The first and second terminals each has a length of about 100 microns. A bias voltage 1020 is electrically coupled across the first and second adhesion contacts 1010-1, 1010-2. A current measurement circuit 1022 is coupled to measure current between through the TMD layer 1004, comprising electrons stimulated to a conducting state by photons that pass through the channel opening 1008 and that are incident upon the third TDM layer portion 1004-3.

The above description is presented to enable any person skilled in the art to create and use a STMDS photodetector. Various modifications to the embodiments will be readily apparent to those skilled in the art, and the generic principles defined herein may be applied to other embodiments and applications without departing from the spirit and scope of the invention. In the preceding description, numerous details are set forth for the purpose of explanation. However, one of ordinary skill in the art will realize that the embodiments in the disclosure might be practiced without the use of these specific details. In other instances, well-known processes are shown in block diagram form in order not to obscure the description of the invention with unnecessary detail. Identical reference numerals may be used to represent different views of the same or similar item in different drawings. Thus, the foregoing description and drawings of examples in accordance with the present disclosure are merely illustrative of the principles of the invention. Therefore, it will be understood that various modifications can be made to the embodiments by those skilled in the art without departing from the spirit and scope of the invention, which is defined in the appended claims.

### REFERENCES

1 Um, D.-S. et al. InGaAs Nanomembrane/Si van der Waals Heterojunction Photodiodes with Broadband and High Photoresponsivity. ACS Applied Materials & Interfaces 8, 26105-26111 (2016).
2 Omnes, F., Monroy, E., Munoz, E. & Reverchon, J. L. Wide bandgap UV photodetectors: A short review of devices and applications. Gallium Nitride Materials andDevices 6473, Artn 64730e (2007).
3 Zhou, Y. H., An, H. N., Gao, C., Zheng, Z. Q. & Wang, B. UV-Vis-NIR photodetector based on monolayer MoS2. Materials Letters 237, 298-302 (2019).
4 Hu, X. et al. High-Performance Flexible Broadband Photodetector Based on Organolead Halide Perovskite. Advanced Functional Materials 24, 7373-7380 (2014).
Fowler, B. et al. Low-light-level CMOS image sensor for digitally fused night vision systems. Vol. 7298 DCS (SPIE, 2009).
6 Essock, E. A., Sinai, M. J., McCarley, J. S., Krebs, W. K. & DeFord, J. K. Perceptual Ability with Real-World Nighttime Scenes: Image-Intensified, Infrared, and Fused-Color Imagery. Human Factors 41, 438-452 (1999).
7 Dutta, A. & Islam, M. S. Novel broadband photodetector for optical communication. Optics East 2005 6014 (2005).
8 Liu, C.-H., Chang, Y.-C., Norris, T. B. & Zhong, Z. Graphene photodetectors with ultra-broadband and high responsivity at room temperature. Nature Nanotechnology 9, 273-278 (2014).
9 Sargent, E. H. Solar Cells, Photodetectors, and Optical Sources from Infrared Colloidal Quantum Dots. Advanced Materials 20, 3958-3964 (2008).
An, X., Liu, F., Jung, Y. J. & Kar, S. Tunable Graphene-Silicon Heterojunctions for Ultrasensitive Photodetection. Nano Letters 13, 909-916 (2013).
11 Buscema, M. et al. Fast and Broadband Photoresponse of Few-Layer Black Phosphorus Field-Effect Transistors. Nano Letters 14, 3347-3352 (2014).
12 Li, C. et al. Ultrafast and broadband photodetectors based on a perovskite/organic bulk heterojunction for large-dynamic-range imaging. Light: Science & Applications 9, 31 (2020).
13 Wang, Q. H., Kalantar-Zadeh, K., Kis, A., Coleman, J. N. & Strano, M. S. Electronics and optoelectronics of two-dimensional transition metal dichalcogenides. Nat Nano 7, 699-712 (2012).
14 Mak, K. F. & Shan, J. Photonics and optoelectronics of 2D semiconductor transition metal dichalcogenides. Nat Photon 10, 216-226 (2016).
Xia, F., Wang, H., Xiao, D., Dubey, M. & Ramasubramaniam, A. Two-dimensional material nanophotonics. Nat Photon 8, 899-907 (2014).
16 Duan, X., Wang, C., Pan, A., Yu, R. & Duan, X. Two-dimensional transition metal dichalcogenides as atomically thin semiconductors: opportunities and challenges. Chemical Society Reviews 44, 8859-8876 (2015).
17 Jariwala, D., Sangwan, V. K., Lauhon, L. J., Marks, T. J. & Hersam, M. C. Emerging Device Applications for Semiconducting Two-Dimensional Transition Metal Dichalcogenides. ACS Nano 8, 1102-1120 (2014).
18 Manzeli, S., Ovchinnikov, D., Pasquier, D., Yazyev, O. V. & Kis, A. 2D transition metal dichalcogenides. Nature Reviews Materials 2, 17033 (2017).
19 Sebastian, A., Pendurthi, R., Choudhury, T. H., Redwing, J. M. & Das, S. Benchmarking monolayer MoS2 and WS2 field-effect transistors. Nature Communications 12, 693 (2021).
20 Yu, H. et al. Wafer-Scale Growth and Transfer of Highly-Oriented Monolayer MoS₂ Continuous Films. ACS Nano 11, 12001-12007 (2017).
21 Li, T. et al. Epitaxial growth of wafer-scale molybdenum disulfide semiconductor single crystals on sapphire. Nature Nanotechnology 16, 1201-1207 (2021).
22 Klots, A. R. et al. Probing excitonic states in suspended two-dimensional semiconductors by photocurrent spectroscopy. Sci. Rep. 4, 6608 (2014).
23 Dumcenco, D. et al. Large-Area Epitaxial Monolayer MoS₂. Acs Nano 9, 4611-4620 (2015).
24 Qiu, D. Y., da Jornada, F. H. & Louie, S. G. Optical Spectrum of MoS₂: Many-Body Effects and Diversity of Exciton States. Physical Review Letters 111, 216805 (2013).
Wang, H. et al. Radiative lifetimes of excitons and trions in monolayers of the metal dichalcogenide MoS₂. Physical Review B 93, 045407 (2016).
26 Britnell, L. et al. Strong Light-Matter Interactions in Heterostructures of Atomically Thin Films. Science 340, 1311-1314 (2013).
27 Palummo, M., Bernardi, M. & Grossman, J. C. Exciton Radiative Lifetimes in Two-Dimensional Transition Metal Dichalcogenides. Nano Letters (2015).
28 Wang, L. et al. Slow cooling and efficient extraction of C-exciton hot carriers in MoS₂ monolayer. Nature Communications 8, 13906 (2017).
29 Tersoff, J. Schottky barriers and semiconductor band structures. Physical Review B 32, 6968-6971 (1985).
Tejedor, C., Flores, F. & Louis, E. The metal-semiconductor interface: Si (111) and zincblende (110) junctions. Journal of Physics C: Solid State Physics 10, 2163-2177 (1977).
31 Monch, W. On the physics of metal-semiconductor interfaces. Reports on Progress in Physics 53, 221-278 (1990).
32 Wang, Y. et al. Van der Waals contacts between three-dimensional metals and two-dimensional semiconductors. Nature 568, 70-74 (2019).
33 Kim, B.-K. et al. Origins of genuine Ohmic van der Waals contact between indium and MoS₂. npj 2D Materials and Applications 5, 9 (2021).
34 Liu, Y. et al. Approaching the Schottky-Mott limit in van der Waals metal-semiconductor junctions. Nature 557, 696-700 (2018).
Telford, E. J. et al. Via Method for Lithography Free Contact and Preservation of 2D Materials. Nano Letters 18, 1416-1420 (2018).
36 Shen, P.-C. et al. Ultralow contact resistance between semimetal and monolayer semiconductors. Nature 593, 211-217 (2021).
37 Kumar, A. et al. Sub-200 ohm-m Alloyed Contacts to Synthetic Monolayer MoS₂. 2021 IEEE International Electron Devices Meeting (IEDM), 7.3.1-7.3.4 (2021).
38 Freitag, M., Low, T., Xia, F. & Avouris, P. Photoconductivity of biased graphene. Nature Photonics 7, 53-59 (2013).
39 Konstantatos, G. et al. Hybrid graphene-quantum dot phototransistors with ultrahigh gain. Nat Nano 7, 363-368 (2012).
Smithe, K. K. H., English, C. D., Suryavanshi, S. V. & Pop, E. High-Field Transport and Velocity Saturation in Synthetic Monolayer MoS₂. Nano Letters 18, 4516-4522 (2018).
41 Yore, A. E. et al. Large array fabrication of high performance monolayer MoS₂ photodetectors. Applied Physics Letters 111, 043110 (2017).
42 Ray, K. et al. Photoresponse of Natural van der Waals Heterostructures. ACS Nano 11, 6024-6030 (2017).
43 Anwar, A., Nabet, B., Culp, J. & Castro, F. Effects of electron confinement on thermionic emission current in a modulation doped heterostructure. Journal of Applied Physics 85, 2663-2666 (1999).
44 Wang, W. et al. Controllable Schottky Barriers between MoS₂ and Permalloy. Scientific Reports 4, 6928 (2014).
Moon, B. H. et al. Junction-Structure-Dependent Schottky Barrier Inhomogeneity and Device Ideality of Monolayer MoS₂ Field-Effect Transistors. ACS Applied Materials & Interfaces 9, 11240-11246 (2017).
46 Ahmetoglu, M. & Akay, S. K. Determination of the parameters for the back-to-back switched Schottky barrier structures. Current Applied Physics 10, 652-654 (2010).
47 Liang, Q. Z., Yao, X. X., Wang, W., Liu, Y. & Wong, C. P. A Three-Dimensional Vertically Aligned Functionalized Multilayer Graphene Architecture: An Approach for Graphene-Based Thermal Interfacial Materials. Acs Nano 5, 2392-2401 (2011). 10.1021/Nn200181e
48 Splendiani, A. et al. Emerging Photoluminescence in Monolayer MoS₂. Nano Letters 10, 1271-1275 (2010).
49 Mak, K. F., Lee, C., Hone, J., Shan, J. & Heinz, T. F. Atomically Thin MoS₂: A New Direct-Gap Semiconductor. Physical Review Letters 105, 136805 (2010).
50 Furchi, M. M., Polyushkin, D. K., Pospischil, A. & Mueller, T. Mechanisms of Photoconductivity in Atomically Thin MoS₂. Nano Letters 14, 6165-6170 (2014).
51 Miller, B., Parzinger, E., Vernickel, A., Holleitner, A. W. & Wurstbauer, U. Photogating of mono- and few-layer MoS2. Applied Physics Letters 106, 122103 (2015).
52 Island, J. O., Blanter, S. I., Buscema, M., van der Zant, H. S. J. & Castellanos-Gomez, A. Gate Controlled Photocurrent Generation Mechanisms in High-Gain In2Se3 Phototransistors. Nano Letters 15, 7853-7858 (2015).
53 Fang, H. & Hu, W. Photogating in Low Dimensional Photodetectors. Advanced Science 4, 1700323 (2017).
54 Huang, H. et al. Highly sensitive visible to infrared MoTe₂ photodetectors enhanced by the photogating effect. Nanotechnology 27, 445201 (2016).
55 Kufer, D. & Konstantatos, G. Highly Sensitive, Encapsulated MoS₂ Photodetector with Gate Controllable Gain and Speed. Nano Letters 15, 7307-7313 (2015).
56 Vaquero, D. et al. Fast response photogating in monolayer MoS₂ phototransistors. Nanoscale 13, 16156-16163 (2021).
57 Lopez-Sanchez, O., Lembke, D., Kayci, M., Radenovic, A. & Kis, A. Ultrasensitive photodetectors based on monolayer MoS₂. Nature Nanotechnology 8, 497-501 (2013). 10.1038/Nnano.2013.100
58 Mangold, K., Shaw, J. A. & Vollmer, M. The physics of near-infrared photography. European Journal ofPhysics 34, S51 (2013).
59 Benson, G. et al. Giant Effects of Interlayer Interaction on Valence-Band Splitting in Transition Metal Dichalcogenides. The Journal of Physical Chemistry C 126, 8667-8675 (2022).
60 Ghosh, S. et al. Ultrafast Intrinsic Photoresponse and Direct Evidence of Sub-gap States in Liquid Phase Exfoliated MoS₂ Thin Films. Scientific Reports 5, Artn 11272 (2015).
61 Chandan, Sarkar, S. & Angadi, B. Defects induced persistent photoconductivity in monolayer MoS₂. Applied Physics Letters 118, 172105 (2021).
62 Fontana, M. et al. Electron-hole transport and photovoltaic effect in gated MoS₂ Schottky junctions. Scientific Reports 3, 1634 (2013).
63 Macdonald, D. & Cuevas, A. Trapping of minority carriers in multicrystalline silicon. Applied Physics Letters 74, 1710-1712 (1999).
64 Haynes, J. R. & Hornbeck, J. A. Temporary Traps in Silicon and Germanium. Physical Review 90, 152-153 (1953).
65 Hornbeck, J. A. & Haynes, J. R. Trapping of Minority Carriers in Silicon. I. P-Type Silicon. Physical Review 97, 311-321 (1955).
66 Ghatak, S., Pal, A. N. & Ghosh, A. Nature of Electronic States in Atomically Thin MoS₂ Field-Effect Transistors. ACS Nano 5, 7707-7712 (2011).
67 Ghatak, S. & Ghosh, A. Observation of trap-assisted space charge limited conductivity in short channel MoS₂ transistor. Applied Physics Letters 103, 122103 (2013).
68 Zhu, W. et al. Electronic transport and device prospects of monolayer molybdenum disulphide grown by chemical vapour deposition. Nature Communications 5, 3087 (2014).
69 Alaie, Z., Mohammad Nejad, S. & Yousefi, M. H. Recent advances in ultraviolet photodetectors. Materials Science in Semiconductor Processing 29, 16-55 (2015).
70 Zhang, X.-M., Tseng, S.-H. & Lu, M.-Y. Large-Area Ultraviolet Photodetectors Based on p-Type Multilayer MoS₂ Enabled by Plasma Doping. Applied Sciences 9, 1110 (2019).
71 Arora, K., Goel, N., Kumar, M. & Kumar, M. Ultrahigh Performance of Self-Powered 0-Ga₂O₃ Thin Film Solar-Blind Photodetector Grown on Cost-Effective Si Substrate Using High-Temperature Seed Layer. ACS Photonics 5, 2391-2401 (2018).

1. An optical detector comprising:
a first semimetal electrical contact portion, comprising a semimetal;
a second semimetal electrical contact portion comprising a semimetal; and
a transition metal dichalcogenide (TMD) layer, comprising a transition metal dichalcogenide, electrically coupled between the first and second semimetal electrical contact portions.

2. The optical detector of claim 1,
wherein the TMD layer includes a first portion, a second portion, and a third portion, wherein the third portion of the TDM layer is located between the first and second portions of the TDM layer;
wherein the first semimetal electrical contact portion is formed upon the first portion of the TDM layer;
wherein the second semimetal electrical contact portion is formed upon the second portion of the TDM layer; further including:
an optical channel, to allow passage of photons to the third portion of the TDM layer, that extends between the first and second semimetal electrical contact portions and that terminates at the third portion of the TDM layer.

3. The optical detector of claim 1 further including:
a conductor layer; and
an insulator layer overlaying the conductor layer;
wherein the TMD layer is formed upon the insulator layer.

4. The optical detector of claim 3 further including:
an undoped silicon layer located between the conductor layer and the insulator layer;
wherein the insulator layer includes a silicon dioxide layer formed upon the undoped silicon layer.

5. The optical detector of claim 4,
wherein the undoped silicon layer has a thickness in a range of about 10 nanometers to 100 nanometers.

6. The optical detector of claim 4,
wherein the conductor layer includes a doped silicon layer.

7. The optical detector of claim 4,
wherein the conductor layer includes a metal layer.

8. The optical detector of claim 2 further including:
a first metal electrical contact portion that overlays at least a portion of the first semimetal electrical contact portion; and
a second metal electrical contact portion that overlays at least a portion of the second semimetal electrical contact portion.

9. The optical detector of claim 8,
a conductor layer; and
an insulator layer overlaying the conductor layer;
wherein the first metal electrical contact portion overlays a portion of the insulator layer; and
wherein the second metal electrical contact portion overlays a portion of the insulator layer;
wherein the TMD layer is formed upon the insulator layer; further including:
a first wetting layer extending between the first metal electrical contact portion and the first semimetal electrical contact portion and extending between the first metal electrical contact portion and the insulator layer; and
a second wetting layer extending between the second metal electrical contact portion and the second semimetal electrical contact portion and extending between the second metal electrical contact portion and the insulator layer.

10. The optical detector of claim 8 further including:
a conductor layer; and
an insulator layer located between the TMD layer and the conductor layer.

11. The optical detector of claim 10 further including:
an undoped semiconductor layer located between the conductor layer and the insulator layer.

12. The optical detector of claim 10,
wherein the conductor layer comprises a doped silicon layer; and
wherein the insulator layer comprises a silicon dioxide layer; further including:
an undoped semiconductor layer located between the conductor layer and the insulator layer.

13. The optical detector of claim 12,
wherein the undoped silicon layer has a thickness in a range of about 10 nanometers to 100 nanometers.

14. The optical detector of claim 1,
wherein the first semimetal electrical contact portion and the second semimetal electrical contact portion include Bismuth; and
wherein the TMD layer includes MoS₂.

15. The optical detector of claim 1,
wherein each occurrence of the semimetal independently comprises As, In, Sn, Sb, Te, TI, Pb, Po, At, Bi, or a mixture thereof, and
wherein the transition metal dichalcogenide comprises WS₂, MoSe₂, WSe₂, MoTe₂, WTe₂, MoS₂, or a mixture thereof.

16. The optical detector of claim 1,
wherein the TMD layer is photoreceptive in an optical wavelength range of about 250 to 1,000 nm.

17. An optical detection method comprising:
receiving optical photon energy at a TMD monolayer electrically coupled between first and second semimetal electrical contacts; and
measuring electrical current flow between the first and second semimetal electrical contacts, comprising electrons excited by optical photon energy received at the TMD layer.

18. The method of claim 17 further including:
applying a bias voltage across the first and second semimetal electrical contacts.

19. The method of claim 17 further including:
applying a voltage to a back gate that is electrically coupled between the first and second semimetal electrical contacts.

20. The method of claim 17 further including:
applying a voltage to a back gate that is electrically coupled between the first and second semimetal electrical contacts; and

21. The method of claim 17,
wherein the STMDS layer is located upon an insulator layer; further including:
preventing current flow between the back gate and the insulator layer.
